(19) United States
(12) Patent Application Publication
(10) Pub. No.: US 2008/0197468 A1
(43) Pub. Date: Aug. 21, 2008

(54) Package structure and manufacturing method thereof

(75) Inventors: Hyeongno Kim, Paju-Si (KR); Soo-Min Choi, Paju-Si (KR); Jae-Sun An, Paju-Si (KR); Young-Gue Lee, Paju-Si (KR); Sang-Jin Cha, Paju-Si (KR)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/706,248

(22) Filed: Feb. 15, 2007

(51) Int. Cl. H01L 23/48

(52) U.S. Cl. 257/686; 257/E23.01

(57) ABSTRACT

A package structure and a manufacturing method thereof are provided. The package structure includes a substrate, a first chip, a cap structure, a second chip and a sealant. The first chip is disposed in an opening of the substrate and is electrically connected to the substrate. The cap structure is disposed on the substrate corresponding to the first chip. The second chip is disposed on the cap structure and is electrically connected to the substrate. The sealant encapsulates the first chip, the cap structure and the second chip.

### BACKGROUND OF THE INVENTION

1. Field of the Invention

The invention relates in general to a package structure and a manufacturing method thereof, and more particularly to a multi-chip package structure and a manufacturing method thereof.

2. Description of the Related Art

Along with the progress of technology, the demand for lightweight, compact size, and multi-function electronic products grows accordingly. In order to reduce the weight and size of the electronic products, semiconductor devices, instead of conventional circuit elements, are utilized inside the electronic products. Besides, electronic products nowadays tend to integrate more and more functions, thus more and more semiconductor devices with complicated micro-electric circuits need to be disposed within the limited space in the electronic products. Regarding the manufacturing process of the semiconductor devices, normally a semiconductor chip is attached on and electrically connected to a substrate via wire-bonding or other bonding processes. So that the semiconductor chip inside the semiconductor device can be electrically connected to the outer circuit through the contacts or pads on the substrate. As the semiconductor devices perform more and more functions, the inner circuits of the semiconductor devices become more complicated than former semiconductor devices, and the number of contacts or pads increases rapidly.

Recently, a multi-chip package structure of semiconductor devices is developed for utilizing the space in the electronic products more effectively. In a semiconductor device with multi-chip package structure, there are several semiconductor chips with different functions disposed on a substrate and packaged integrally inside this single semiconductor device. However, electromagnetic radiation is generated when the semiconductor chips operate, which results in the electromagnetic interference between the semiconductor chips. What makes the interference even worse is the miniature of the semiconductor devices. Along with the miniature of the semiconductor devices, the size of the package structure is decreased. The distance between the semiconductor chips in each semiconductor device with multi-chip package is reduced significantly, and the interference between the semiconductor chips becomes more serious. When the semiconductor chips interfere with each other, more errors occur during chip operation, and the quality of the electronic products is degraded accordingly. Therefore, there exists a major difficulty regarding maintaining the stability of chip operation while miniaturizing the semiconductor devices.

### SUMMARY OF THE INVENTION

The invention is directed to a package structure and a manufacturing method thereof. A cap structure disposed on a first chip covers the entire first chip, and the electromagnetic radiation generated by the first chip and a second chip is sheltered by the cap structure accordingly. As a result, the interference between the first chip and the second chip is lowered when the chips operate. Therefore, the package structure has advantages including high stability, high quality, small size and low developing cost.

According to the present invention, a package structure including a substrate, a first chip, a cap structure, a second chip and a sealant is provided. The substrate has an opening, and the first chip disposed in the opening is electrically connected to the substrate. The cap structure is disposed on the substrate corresponding to the first chip. The second chip disposed on the cap structure is electrically connected to the substrate. The sealant encapsulates the first chip, the cap structure and the second chip.

According to the present invention, another package structure including a substrate, a first chip, a cap structure, a first sealant, a second chip and a second sealant is provided. The first chip disposed on the substrate is electrically connected to the substrate. The cap structure is disposed on the substrate corresponding to the first chip. The first sealant encapsulates the first chip and the cap structure. The second chip disposed on the first sealant is electrically connected to the substrate. The second sealant encapsulates the first sealant and the second chip.

The invention will become apparent from the following detailed description of the preferred but non-limiting embodiments. The following description is made with reference to the accompanying drawings.

### BRIEF DESCRIPTION OF THE DRAWINGS

FIG. 1A illustrates a substrate according to a first embodiment of the invention;

FIG. 1B illustrates an adhesive film disposed on a lower surface of the substrate in FIG. 1A;

FIG. 1C illustrates a first chip adhered to the adhesive film in FIG. 1B;

FIG. 1D illustrates a cap structure disposed on the substrate in FIG. 1C;

FIG. 1E illustrates a second chip bonded to the cap structure in FIG. 1D;

FIG. 1F illustrate a sealant formed on the substrate in FIG. 1E;

FIG. 1G shows a top view of the cap structure in FIG. 1F;

FIG. 2 illustrates the package structure according to the first embodiment of the invention;

FIG. 3A illustrates a substrate according to a second embodiment of the invention;

FIG. 3B illustrates a first chip disposed on the substrate in FIG. 3A;

FIG. 3C illustrates a cap structure disposed on the substrate in FIG. 3B;

FIG. 3D illustrates a first sealant formed on the substrate in FIG. 3C;

FIG. 3E illustrates a second chip disposed on the first sealant in FIG. 3D;

FIG. 3F illustrates a second sealant formed on the substrate in FIG. 3E; and

FIG. 4 illustrates the package structure according to the second embodiment of the invention.

### DETAILED DESCRIPTION OF THE INVENTION

Two embodiments are provided as follow to elaborate the details of the invention. The difference between these two embodiments lies in the disposition of the first chip. However, theses embodiments are used as examples not for limiting the scope of protection of the invention. The embodiments are encompassed in the scope defined in the appended claims of the invention. Furthermore, unnecessary components are not shown in the drawings for clarifying the technical features of the invention.

### First Embodiment

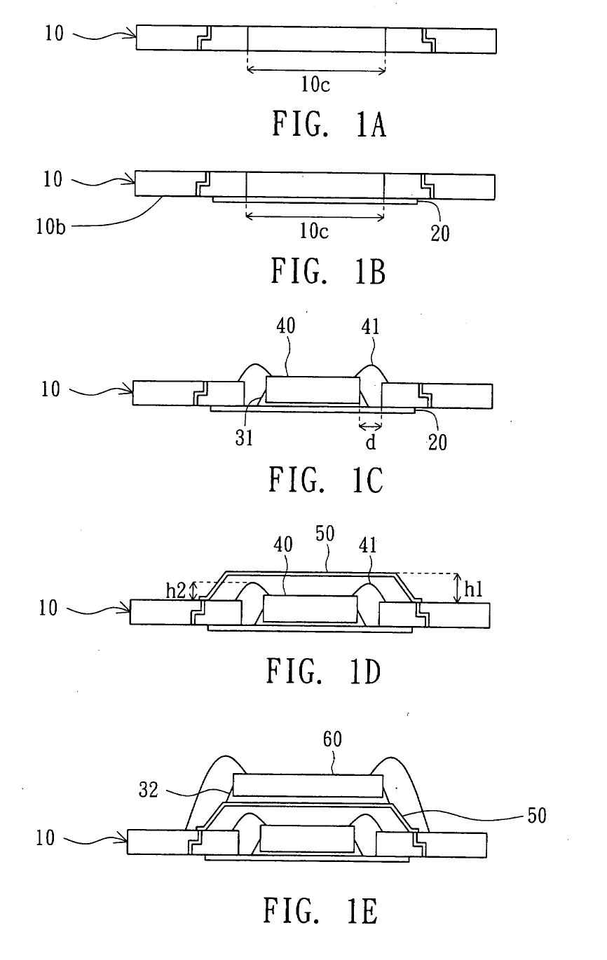

FIG. 1A illustrates a substrate according to a first embodiment of the invention. FIG. 1B illustrates an adhesive film disposed on a lower surface of the substrate in FIG. 1A. FIG. 1C illustrates a first chip adhered to the adhesive film in FIG. 1B. FIG. 1D illustrates a cap structure disposed on the substrate in FIG. 1C. FIG. 1E illustrates a second chip bonded to the cap structure in FIG. 1D. FIG. 1F illustrate a sealant formed on the substrate in FIG. 1E.

Please refer to FIGS. 1A-1F. A manufacturing method of a package structure according to the first embodiment of the invention includes following steps. First, a substrate 10 having an opening 10c is provided, as shown in FIG. 1A.

Next, an adhesive film 20 is provided on a lower surface 10b of the substrate 10. The opening 10c exposes a portion of the adhesive film 20. In other words, the area of the adhesive film 20 is preferably larger than that of the opening 10c, as shown in FIG. 1B.

Then, a first chip 40 is adhered to the adhesive film 20 and wire-bonded to the substrate 10 through a gold wire 41. The first chip 40 is adhered to the adhesive film 20 through a first adhesive layer 31, for disposing the first chip 40 in the opening 10c. As shown in FIG. 1C, the area of the opening 10c (shown in FIG. 1B) is preferably larger than that of the first chip 40, so that a gap d is formed between the first chip 40 and an inner wall of the opening 10c. As a result, the first chip 40 does not contact the substrate 10, as shown in FIG. 1C.

Afterwards, a cap structure 50 is disposed on the substrate 10. The cap structure 50 is disposed corresponding to the first chip 40, so that the cap structure 50 covers the entire first chip 40. As shown in FIG. 1D, the cap structure 50 has a height h1, and the wire loop of the gold wire 41 has a second height h2. The first height h1 is greater than the second height h2. Therefore, the cap structure 50 does not contact the gold wire 41.

Later, as shown in FIG. 1E, a second chip 60 is disposed on the cap structure 50 and is wire-bonded to the substrate 10. The second chip 60 is adhered to the cap structure 50 through a second adhesive layer 32.

Thereon, as shown in FIG. 1F, a sealant 80 is formed on the substrate 10. Please refer to FIG. 1G, which is a top view of the cap structure in FIG. 1F. Several concave edges 50a are preferably formed at the cap structure 50. As a result, when the sealant 80 is formed, the material enters the cap structure 50 through the concave edges 50a. Therefore, the sealant 80 is formed not only on an upper surface 10a of the substrate 10, but also in the cap structure 50 and in the gap d. In other words, the sealant 80 encapsulates the first chip 40, the cap structure 50 and the second chip 60.

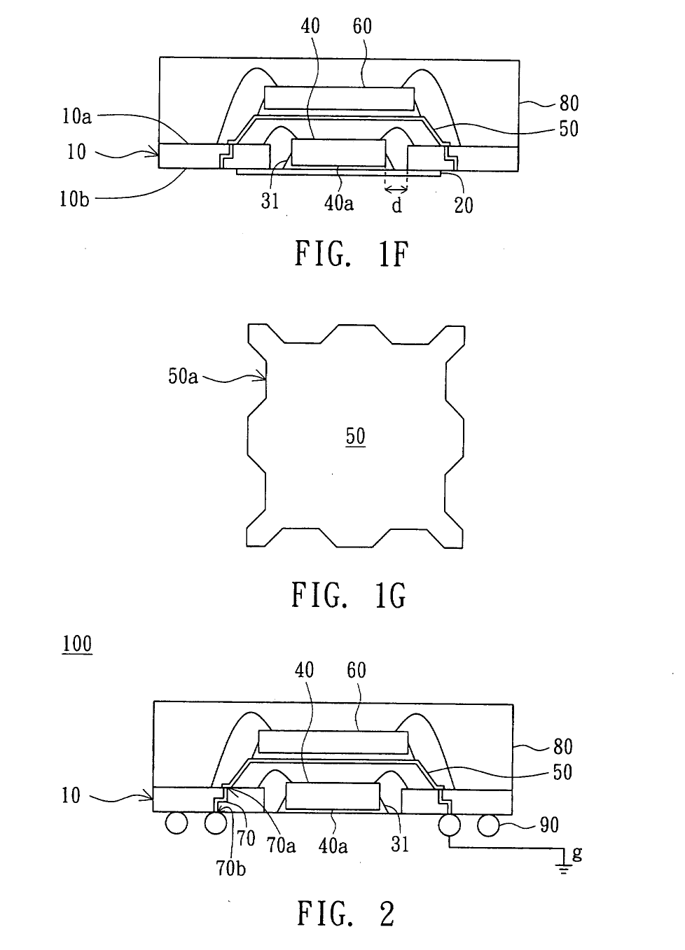

Then, the adhesive film 20 is removed, and a grounding tin ball is disposed on the lower surface 10b. After the adhesive film 20 is removed, the first adhesive layer 31 still attached on a bottom surface 40a of the first chip 40 for protecting the first chip 40. Preferably, a heat sink can be disposed under the first chip 40 and the first adhesive layer 31 for cooling the first chip 40. After the step of removing the adhesive film 20 and disposing the grounding ball, the package structure according to the first embodiment of the invention is accomplished. Please refer to FIG. 2, which illustrates the package structure according to the first embodiment of the invention. The package structure 100 includes the substrate 10, the first chip 40, the cap structure 50, the second chip 60, the grounding ball 90 and the sealant 80.

Moreover, the package structure 100 further includes a conductive trace 70, as shown in FIG. 2. The conductive trace 70 is disposed in the substrate 10 for electrically connecting the upper surface 10a and the lower surface 10b of the substrate 10. One end 70a of the conductive trace 70 is connected to the cap structure 50, and the other end 70b of the conductive trace 70 is connected to the grounding tin ball 90. Preferably, the cap structure 50 of the present embodiment is conductive material and is electrically connected to a ground plane g through the conductive trace 70 and the grounding ball 90. Moreover, the first adhesive layer 31 and the second adhesive layer 32 are silver epoxy layers for example.

In the package structure and the manufacturing method thereof according to the first embodiment of the invention, the cap structure 50 is disposed between the first chip 40 and the second chip 60 and is electrically connected to the ground plane g. As a result, the electromagnetic radiation generated by the first chip 40 and the second chip 60 is sheltered by the cap structure 50, so that the first chip 40 and the second chip 60 do not interfere with each other. Therefore, the accuracy of the chip operation increases, and the stability of the products is further improved.

### Second Embodiment

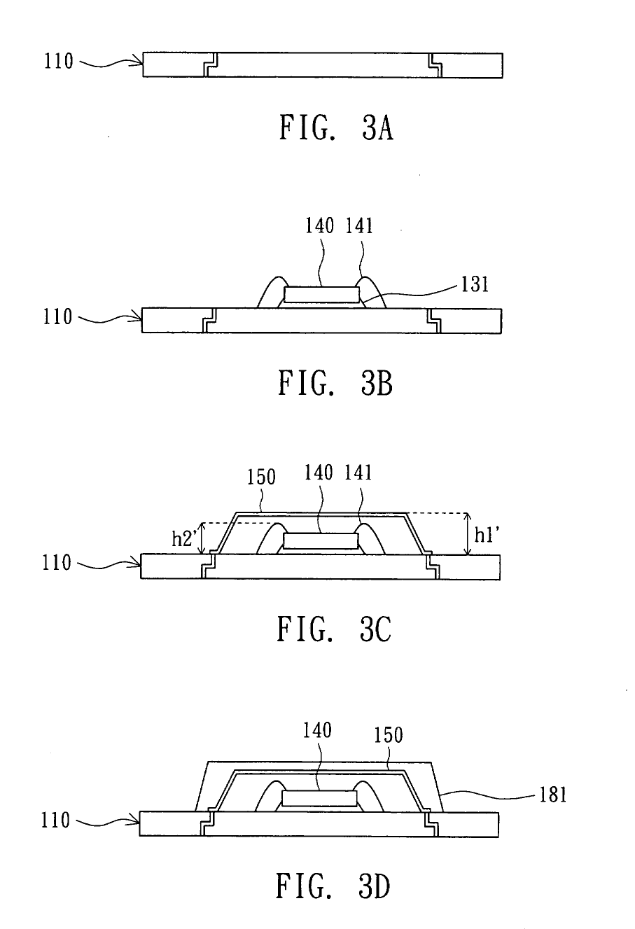

Please refer to FIGS. 3A-3F. FIG. 3A illustrates a substrate according to a second embodiment of the invention. FIG. 3B illustrates a first chip disposed on the substrate in FIG. 3A. FIG. 3C illustrates a cap structure disposed on the substrate in FIG. 3B. FIG. 3D illustrates a first sealant formed on the substrate in FIG. 3C. FIG. 3E illustrates a second chip disposed on the first sealant in FIG. 3D. FIG. 3F illustrates a second sealant formed on the substrate in FIG. 3E.

A manufacturing method of a package structure according to the second embodiment of the invention includes following steps. First, a substrate 110 is provided, as shown in FIG. 3A.

Next, a first chip 140 is adhered to the substrate 110 through a first adhesive layer 131. The first chip 140 is wire-bonded to the substrate 110 through a gold wire 141, as shown in FIG. 3B.

Then, a cap structure 150 is disposed on the substrate 110 corresponding to the first chip 140, as shown in FIG. 3C. The cap structure 150 covers the entire first chip 140. The cap structure 150 has a height h1′, and the wire loop of the gold wire 141 has a height h2′. The height h1′ is greater than the height h2′. Therefore, the cap structure 150 does not contact the gold wire 141 for preventing short circuits.

Furthermore, as shown in FIG. 3D, a first sealant 181 is formed on the substrate 110. The cap structure 150 of the present embodiment is preferably the same as the cap structure 50 of the first embodiment that has several concave edges 50a (as shown in FIG. 2). Therefore, the first sealant 181 can also fill into the cap structure 150. In other words, the first sealant 181 encapsulates the first chip 140 and the cap structure 150. Besides, the first sealant 181 only encapsulates a portion of the substrate 10.

Afterwards, as shown in FIG. 3E, a second chip 160 is adhered to the first sealant 181 through a second adhesive layer 132. The second chip 160 is wire-bonded to the substrate 110.

Later, as shown in FIG. 3F, a second sealant 182 is formed on the substrate 110. The second sealant 182 encapsulates the first sealant 181 and the second chip 160.

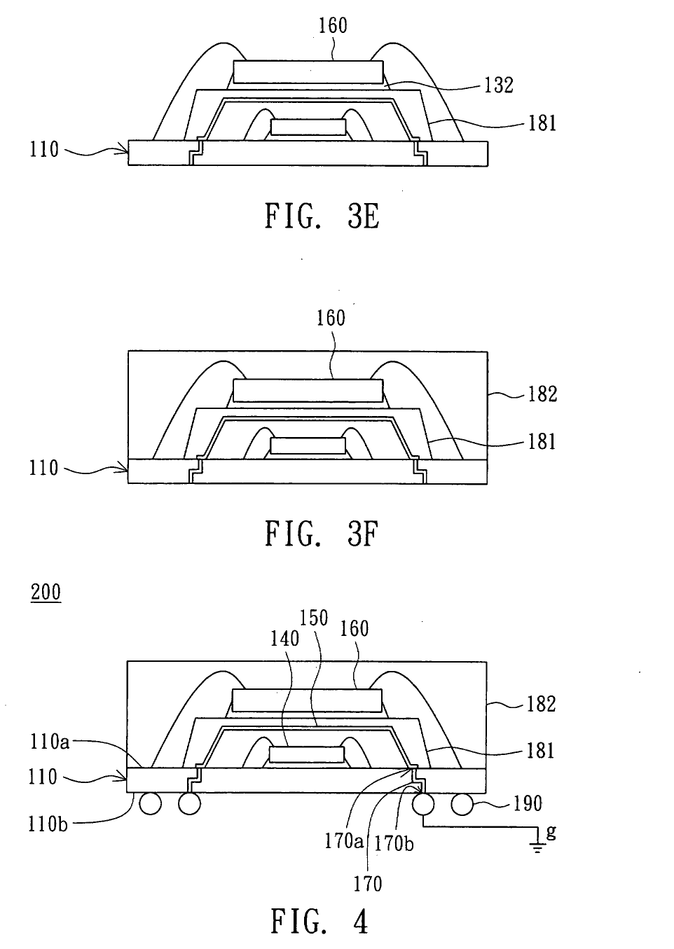

Thereon, a grounding ball is disposed on a lower surface of the substrate 110. After the grounding ball is disposed, the package structure according to the second embodiment of the invention is accomplished. Please referring to FIG. 4, the package structure according to the second embodiment of the invention is illustrated in FIG. 4. The package structure 200 includes the substrate 110, the first chip 140, the cap structure 150, the first sealant 181, the second chip 160, the second sealant 182 and the grounding ball 190.

In addition, the package structure further includes a conductive trace 170. The conductive trace 170 is used for electrically connecting the upper surface 110a and the lower surface 110b of the substrate 110. One end 170a of the conductive trace 170 is connected to the cap structure 150. The other end 170b of the conductive trace 170 is connected to the grounding ball 190. Preferably, the cap structure 150 is electrically conductive and is electrically connected to a ground plane g through the conductive trace 170 and the grounding ball 190. Moreover, the first adhesive layer 131 and the second adhesive layer 132 of the present embodiment are silver epoxy layers for example.

In the package structure 200 and the manufacturing method thereof according to the second embodiment of the invention, the second chip 160 is disposed on the first sealant 181. As a result, while wire bonding the second chip 160 to the substrate 110, the second chip 160 and the cap structure 150 are prevented from bending or even breaking due to pressing by the supporting of the first sealant 181. Furthermore, because the second chip 160 is supported by the first sealant 181, not by the cap structure 150, the cap structure 150 may have a reduced volume to lower its material cost.

In the package structure and the manufacturing method thereof according to the embodiments of the invention, the cap structure covers the first chip, so that the electromagnetic radiation generated by the first chip and the second chip is sheltered. The chips do not interfere with each other, and the chips operate more stably. As a result, the quality of the product is improved. Moreover, the sheltering can be achieved only by adding the cap structure into the conventional package structure; for this reason, the package structure according to the embodiments of the invention is compatible with the conventional manufacturing method. Therefore, the cost of developing a new manufacturing process is saved. Furthermore, the volume of the package structure is reduced by disposing the first chip in the opening of the substrate. Also, due to the supporting of the first sealant, the cap structure and the second chip are prevented from bending or breaking while wire bonding the second chip to the substrate. Therefore, the yield rate of the products is increased. Besides, it is the first sealant, not the cap structure, which supports the second chip, so the volume of the cap structure is decreased. As a result, the material cost of the cap structure is reduced.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure comprising:
a substrate having an opening;
a first chip disposed in the opening and electrically connected to the substrate;
a cap structure disposed on the substrate corresponding to the first chip;
a second chip disposed on the cap structure and electrically connected to the substrate; and
a sealant encapsulating the first chip, the cap structure and the second chip.

2. The package structure according to claim 1, wherein the area of the opening is larger than the area of the first chip, so that a gap is formed between the first chip and an inner wall of the opening.

3. The package structure according to claim 2, wherein the sealant is further disposed between the first chip and the inner wall.

4. The package structure according to claim 1, wherein the first chip is wire-bonded to the substrate through a gold wire.

5. The package structure according to claim 4, wherein the cap structure has a first height and the wire loop of the gold wire has a second height, the first height is greater than the second height.

6. The package structure according to claim 1 further comprising:
a grounding ball disposed on a lower surface of the substrate; and
a conductive trace electrically connecting an upper surface and the lower surface of the substrate, one end of the conductive trace electrically connected to the cap structure, the other end of the conductive trace electrically connected to the grounding ball.

7. The package structure according to claim 6, wherein the cap structure is conductive material and electrically connected to a ground plane through the conductive trace and the grounding ball.

8. The package structure according to claim 1, wherein the second chip is electrically connected to the substrate through wire bonding.

9. The package structure according to claim 1 further comprising a first adhesive layer disposed on the lower surface of the first chip.

10. The package structure according to claim 9, wherein the first adhesive layer is a silver epoxy layer.

11. The package structure according to claim 1 further comprising a heat sink disposed under the first chip.

12. The package structure according to claim 1, wherein the second chip is attached on the cap structure through a second adhesive layer.

13. The package structure according to claim 12, wherein the second adhesive layer is a silver epoxy layer.

14. A package structure comprising:
a substrate;
a first chip disposed on the substrate and electrically connected to the substrate;
a cap structure disposed on the substrate corresponding to the first chip;
a first sealant encapsulating a portion of the substrate, the first chip and the cap structure;
a second chip disposed on the first sealant and electrically connected to the substrate; and
a second sealant encapsulating the substrate, the first sealant and the second chip.

15. The package structure according to claim 14, wherein the first chip is wire-bonded to the substrate through a gold wire.

16. The package structure according to claim 15, wherein the cap structure has a first height and the wire loop of the gold wire has a second height, the first height is greater than the second height.

17. The package structure according to claim 14 further comprising:
a grounding ball disposed on a lower surface of the substrate; and
a conductive trace electrically connecting an upper surface and the lower surface of the substrate, one end of the conductive trace electrically connected to the cap structure, the other end of the conductive trace electrically connected to the grounding ball.

18. The package structure according to claim 17, wherein cap structure is conductive material and electrically connected to a ground plane through the conductive trace and the grounding ball.

19. The package structure according to claim 14, wherein the second chip is electrically connected to the substrate through wire bonding.

20. The package structure according to claim 14 further comprising a first adhesive layer disposed between the first chip and the substrate, and a second adhesive layer disposed between the second chip and the first sealant.

21. The package structure according to claim 20, wherein the first adhesive layer and the second adhesive layer are silver epoxy layers.

22. The package structure according to claim 14, wherein the area of the second chip is larger than the area of the first chip.
